(19) United States
(12) Patent Application Publication
(10) Pub. No.: US 2016/0183379 A1
(43) Pub. Date: Jun. 23, 2016

(54) SUBSTRATE COMPRISING AN EMBEDDED CAPACITOR

(71) Applicant: QUALCOMM Incorporated, San Diego, CA (US)

(72) Inventors: Young Kyu Song, San Diego, CA (US); Hong Bok We, San Diego, CA (US); Kyu-Pyung Hwang, San Diego, CA (US)

(21) Appl. No.: 14/579,735

(22) Filed: Dec. 22, 2014

(51) Int. Cl. H05K 1/18; H05K 3/32

(52) U.S. Cl. CPC H05K 1/185; H05K 3/32

(57) ABSTRACT

A substrate that includes a first dielectric layer and a capacitor embedded in the first dielectric layer. The capacitor includes a base portion, a first terminal and a second terminal. The first terminal is located on a first surface of the base portion, where the first terminal is the only terminal on the first surface of the base portion. The second terminal is located on a second surface of the base portion. The second surface is opposite to the first surface. The second terminal is the only terminal on the second surface of the base portion. In some implementations, the capacitor further includes a first base metal layer located between the first surface of the base portion and the first terminal. In some implementations, the capacitor also includes a second base metal layer located between the second surface of the base portion and the second terminal.

### BACKGROUND

1. Field

Various features relate to a substrate that includes an embedded capacitor.

2. Background

FIG. 1 illustrates a conventional configuration of an integrated package that includes a die. Specifically, FIG. 1 illustrates an integrated package 100 that includes a package substrate 104 and a first die 106. The integrated package 100 is coupled to a printed circuit board (PCB) 102 through a first set of solder balls 105. The first die 106 is coupled to the package substrate 104 through a second set of solder balls 107. The package substrate 104 includes one or more dielectric layers 110, and a set of interconnects 112 (e.g., traces and vias). The set of interconnects 112 is coupled to the first and second set of solder balls 105 and 107. A capacitor 120 is coupled to the PCB 102. The capacitor 120 is located near the integrated package 100 on the PCB 102. The capacitor 120 may be used as a decoupling capacitor in a power distribution network.

One drawback of the integrated package 100 and capacitor 120 shown in FIG. 1 is that it creates an integrated device with a form factor that may be too large for the needs of mobile computing devices. This may result in a package that is either too large and/or too thick. That is, the integrated package and capacitor combination shown in FIG. 1 may be too thick and/or have a surface area that is too large to meet the needs and/or requirements of mobile, wearable or portable computing devices. For example, the placement of the capacitor 120 laterally to the integrated package 100 creates a surface area on the PCB 102 that may be too large to meet the needs mobile, wearable or portable computing devices.

Therefore, there is a need for an integrated device that includes a capacitor that utilizes less space while at the same time provides better capacitive capabilities. Ideally, such an integrated device will have a better form factor, while at the same time meeting the needs and/or requirements of mobile, wearable or portable computing devices.

### SUMMARY

Various features, apparatus and methods described herein a substrate that includes a capacitor.

A first example provides a substrate that includes a first dielectric layer and a capacitor embedded in the first dielectric layer. The capacitor includes a base portion, a first terminal located on a first surface of the base portion. The first terminal is the only terminal on the first surface of the base portion. The capacitor includes a second terminal located on a second surface of the base portion. The second surface is opposite to the first surface. The second terminal is the only terminal on the second surface of the base portion.

A second example provides a method for fabricating a substrate. The method forms a first dielectric layer. The method embeds a capacitor in the first dielectric layer. The method of embedding the capacitor includes forming a base portion and forming a first terminal on a first surface of the base portion. The first terminal is the only terminal on the first surface of the base portion. The method of embedding the capacitor includes forming a second terminal on a second surface of the base portion. The second surface is opposite to the first surface. The second terminal is the only terminal on the second surface of the base portion. The method of embedding the capacitor also includes positioning the base portion, the first terminal, and the second terminal in the first dielectric layer.

### DRAWINGS

Various features, nature and advantages may become apparent from the detailed description set forth below when taken in conjunction with the drawings in which like reference characters identify correspondingly throughout.

FIG. 1 illustrates a conventional integrated device package next to a capacitor.

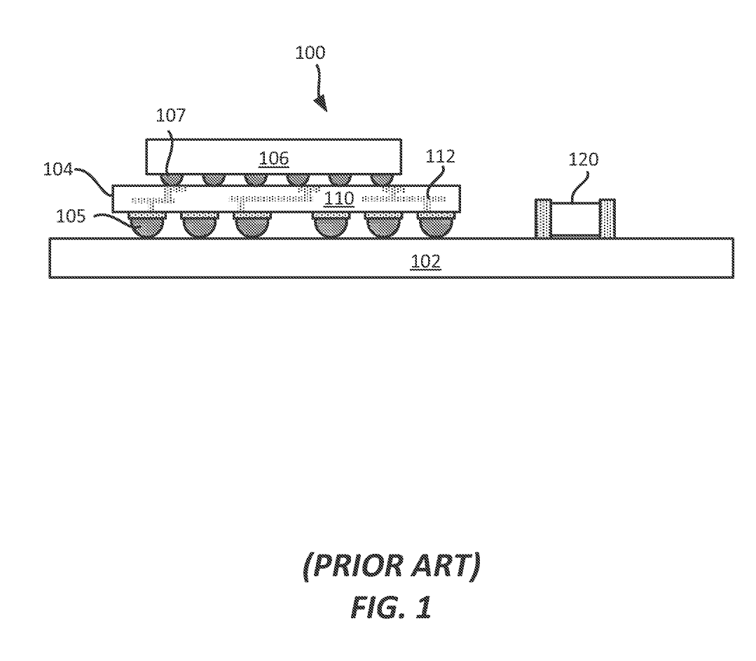

FIG. 2 illustrates an example of a capacitor.

FIG. 3 illustrates an example of a profile view of a cross section of a capacitor.

FIG. 4 illustrates an example of a plan view of a cross section of a capacitor.

FIG. 5 illustrates an example of a plan view of another cross section of a capacitor.

FIG. 6 illustrates another example of a capacitor.

FIG. 7 illustrates an example of a profile view of a capacitor embedded in a substrate.

FIG. 8 illustrates an example of a profile view of a capacitor embedded in another substrate.

FIG. 9 illustrates an exemplary sequence for providing/fabricating a capacitor.

FIG. 10 illustrates another exemplary sequence for providing/fabricating a capacitor.

FIG. 11 illustrates an exemplary flow diagram of a method for providing/fabricating a capacitor.

FIG. 12 (comprising FIGS. 12A-12C) illustrates an exemplary sequence for providing/fabricating a substrate that includes an embedded capacitor.

FIG. 13 (comprising FIGS. 13A-13C) illustrates an exemplary sequence for providing/fabricating a substrate that includes an embedded capacitor.

FIG. 14 illustrates an exemplary flow diagram of a method for providing/fabricating a substrate that includes an embedded capacitor.

FIG. 15 illustrates an example of a semi-additive patterning (SAP) process.

FIG. 16 illustrates an example of flow diagram of a semi-additive patterning (SAP) process.

FIG. 17 illustrates an example of a damascene process.

FIG. 18 illustrates an example of a flow diagram of a damascene process.

FIG. 19 illustrates various electronic devices that may integrate an integrated device, an integrated device package, a semiconductor device, a die, an integrated circuit, a substrate, an interposer and/or PCB described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

### Overview

Some features pertain to a substrate (e.g., a package substrate, an interposer) that includes a first dielectric layer and a capacitor embedded in the first dielectric layer. The capacitor includes a base portion, a first terminal and a second terminal. The first terminal is located on a first surface of the base portion, where the first terminal is the only terminal on the first surface of the base portion. The second terminal is located on a second surface of the base portion. The second surface is opposite to the first surface. The second terminal is the only terminal on the second surface of the base portion. In some implementations, the capacitor further includes a first base metal layer located between the first surface of the base portion and the first terminal. In some implementations, the capacitor also includes a second base metal layer located between the second surface of the base portion and the second terminal. The substrate also includes a first terminal interconnect coupled to the first terminal of the capacitor, and a second terminal interconnect coupled to the second terminal of the capacitor. The first terminal interconnect is coupled to the first terminal such that a substantial part of a horizontal portion of the first terminal is in contact with the first terminal interconnect. The second terminal interconnect is coupled to the second terminal such that a substantial part of a horizontal portion of the second terminal is in contact with the second terminal interconnect. The first terminal interconnect is coupled to the first terminal such that a majority of a horizontal portion of the first terminal is in contact with the first terminal interconnect.

In some implementation, an interconnect is an element or component of a device (e.g., integrated device, integrated device package, die) and/or a base (e.g., package substrate, printed circuit board, interposer) that allows or facilitates an electrical connection between two points, elements and/or components. In some implementations, an interconnect may include a trace, a via, a pad, a pillar, a redistribution metal layer, and/or an under bump metallization (UBM) layer. In some implementations, an interconnect is an electrically conductive material that provides an electrical path for a signal (e.g., data signal, ground signal, power signal). An interconnect may include more than one element/component.

### Exemplary Capacitor

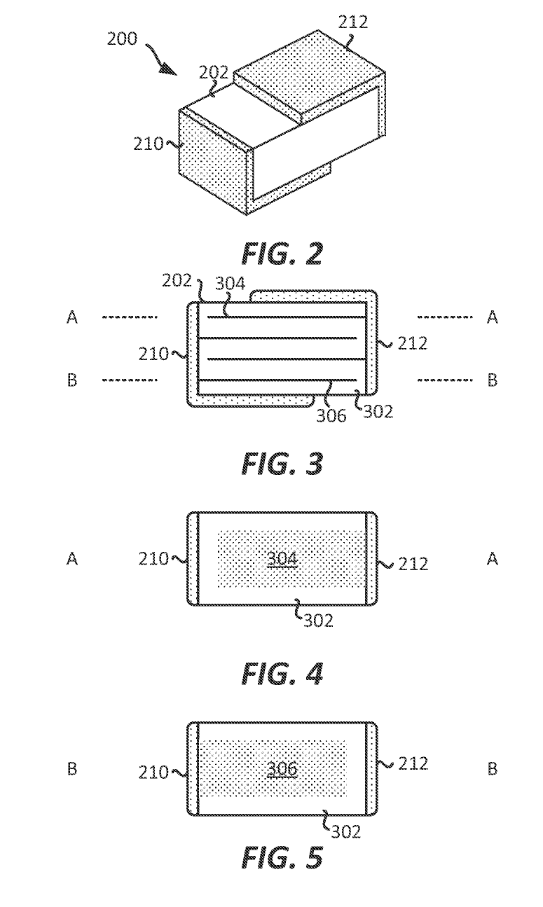

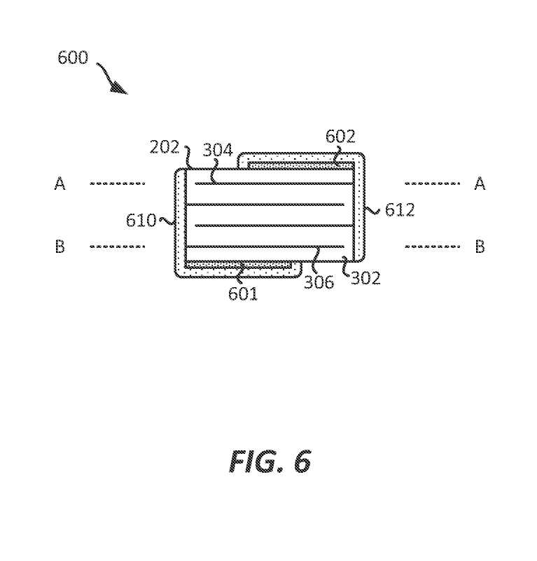

FIG. 2 illustrates an example of a capacitor 200. The capacitor 200 includes a base portion 202, a first terminal 210, and a second terminal 212. The base portion 202 includes one or more dielectric layers and several metal layers (e.g., metal plates, electrically conductive plates). The dielectric layers and several metal layers are further described in FIGS. 3-5 below.

The first terminal 210 is coupled to a first side portion (e.g., a first side wall) and a first surface portion (e.g., a bottom surface) of the base portion 202. The second terminal 212 is coupled to a second side portion (e.g., a second side wall) and a second surface portion (e.g., a top surface) of the base portion 202. The first side portion is opposite to the second side portion. The first surface portion is opposite to the second surface portion. In some implementations, the first terminal 210 and the second terminal 212 do not share a surface portion on the base portion 202. That is, in some implementations, the first terminal 210 and the second terminal 212 are physically coupled to the base portion 202 such that the first terminal 210 and the second terminal 212 are not located on a same surface and/or side of the base portion 202. However, in some implementations, the first terminal 210 and the second terminal 212 may share a same surface on the base portion 202, without affecting the operation of the capacitor 200.

The first terminal 210 and the second terminal 212 are conductive materials (e.g., one or more metal layers), where each terminal is coupled (e.g., electrically coupled) to one or more of the metal layers in the base portion 202. Examples of metal layers are further described below in at least FIGS. 3-5. In some implementations, the capacitor 200 is a multi layer ceramic capacitor (MLCC). In some implementations, the capacitor 200 is embedded in a substrate, such as a packaging substrate and/or an interposer.

In some implementations, the capacitor 200 has a lateral dimension (e.g., width, length) of about 0.5 millimeter (mm) or less, and a vertical dimension (e.g., height) of about 0.1 millimeter (mm) or less.

FIG. 3 illustrates an example of a profile view of a cross section of the capacitor 200 of FIG. 2. As shown in FIG. 3, the base portion 202 of the capacitor 200 includes a dielectric layer 302 and several metal layers (e.g., first set of metal layers and a second set of metal layers). For example, the base portion 202 includes a first metal layer 304 and a second metal layer 306. The first metal layer 304 (e.g., first metal plate) is part of a first set of metal layers, and the second metal layer 306 (e.g., second metal plate) is part of a second set of metal layers. Although FIG. 3 illustrates a base portion 202 that includes four (4) metal layers, different implementations may include a different number of metal layers with different configurations and combinations of different metal layers. The dielectric layer 302 may include several dielectric layers.

The first set of metal layers (which includes the first metal layer 304) may be configured to electrically provide a first path for a first signal (e.g., ground reference, power signal, I/O signal). The first metal layer 304 is coupled to the second terminal 212. The second set of metal layers (which includes the second metal layer 306) may be configured to electrically provide a second path for a second signal (e.g., ground reference, power signal, I/O signal) that is different than the first signal. The second metal layer 306 is coupled to the first terminal 210.

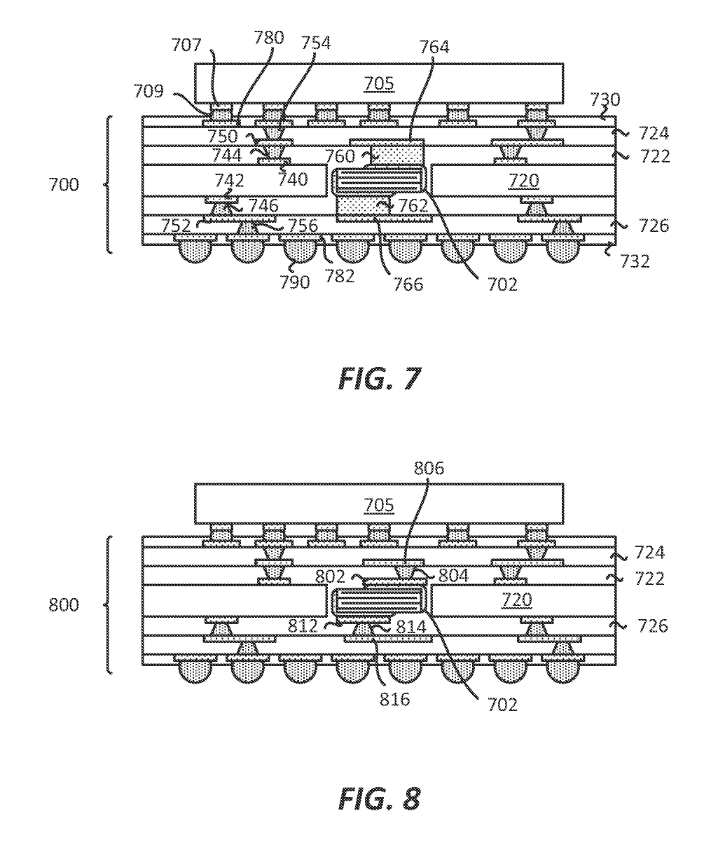

FIG. 4 illustrates an example of a plan view of cross section AA of the capacitor 200 of FIG. 3. As shown in FIG. 4, the first metal layer 304 is embedded in the dielectric layer 302. The first metal layer 304 has a first design and a first shape. In some implementations, all the first set of metal layers have the same first design and first shape. The first metal layer 304 is coupled (e.g., electrically coupled) to the second terminal 212. As further shown in FIG. 4, the first metal layer 304 is not in direct contact (e.g., free of direct contact) with the first terminal 210.

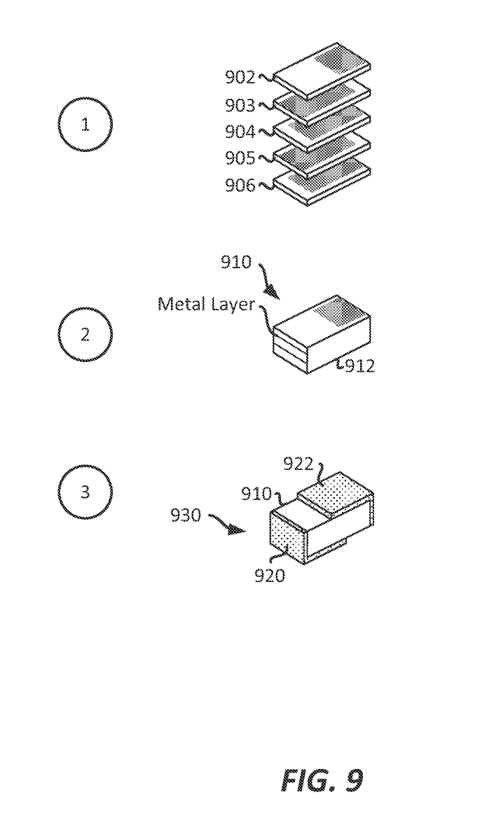

FIG. 5 illustrates an example of a plan view of cross section BB of the capacitor 200 of FIG. 3. As shown in FIG. 5, the second metal layer 306 is embedded in the dielectric layer 302. The second metal layer 306 has a second design and a second shape. In some implementations, all the second set of metal layers have the same second design and second shape. In some implementations, the second design and second shape are different than the first design and the first shape. The second metal layer 306 is coupled (e.g., electrically coupled) to the first terminal 210. As further shown in FIG. 5, the second metal layer 306 is not in direct contact (e.g., free of direct contact) with the second terminal 212.

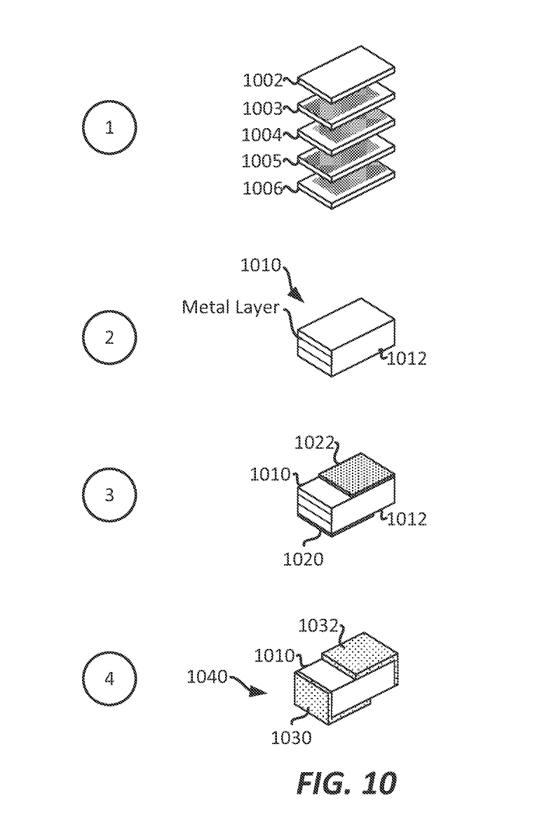

FIG. 6 illustrates an example of another capacitor 600. The capacitor 600 includes the base portion 202, a first base metal layer 601, a second base metal layer 602, a first terminal 610, and the second terminal 612. The base portion 202 includes one or more dielectric layers and several metal layers (e.g., metal plates, electrically conductive plates), as described above. The first base metal layer 601 is located on a first surface (e.g., bottom surface) of the base portion 202. The first base metal layer 601 is covered by the first terminal 610. The second base metal layer 602 is located a second surface (e.g., top surface) of the base portion 202. The second base metal layer 602 is covered by the second terminal 612.

The first terminal 610 is coupled to a first side portion (e.g., a first side wall) and a first surface portion (e.g., a bottom surface) of the base portion 202. The second terminal 612 is coupled to a second side portion (e.g., a second side wall) and a second surface portion (e.g., a top surface) of the base portion 202. The first side portion is opposite to the second side portion. The first surface portion is opposite to the second surface portion. In some implementations, the first terminal 610 and the second terminal 612 do not share a surface on the base portion. That is, in some implementations, the first terminal 610 and the second terminal 612 are physically coupled to the base portion 202 such that the first terminal 610 and the second terminal 612 are not located on a same surface portion of the base portion 202. However, in some implementations, the first terminal 610 and the second terminal 612 may share a same surface and/or side, without affecting the operation of the capacitor 600.

The first terminal 610 and the second terminal 612 are conductive materials (e.g., one or more metal layers), where each terminal is coupled (e.g., electrically coupled) to one or more of the metal layers in the base portion 202. In some implementations, the capacitor 600 is a multi layer ceramic capacitor (MLCC). In some implementations, the capacitor 600 is embedded in a substrate, such as a packaging substrate and/or an interposer.

In some implementations, the capacitor 600 has a lateral dimension (e.g., width, length) of about 0.5 millimeter (mm) or less, and a vertical dimension (e.g., height) of about 0.1 millimeter (mm) or less.

One advantage of the capacitors 200 and/or 600 is that they can be implemented in a substrate, where the terminals can be directly coupled (e.g., directly connected) to traces and/or pads. Normally, vias are directly coupled to the terminals of the capacitors. However, since the terminals of the capacitors are not located on the same surface of the capacitor, vias are not required to directly couple to the terminals. Vias may still be indirectly coupled to the terminals. By taking away the necessity of vias to be directly coupled to the capacitors, a substrate with a smaller dimensions (e.g., thinner substrate) may be fabricated. Notwithstanding the above, vias in a substrate may be directly coupled to the terminals of the capacitors 200 and/or 600.

Additionally, when traces or interconnects that are larger than vias are coupled to the terminals of the capacitor, the capacitor has a lower intrinsic equivalent series inductance (ESL) value than a comparably sized capacitor. A lower intrinsic ESL for the capacitor leads to better signal performance, and therefore better device performance. When vias are directly coupled to the terminals, the vias couple to less than a majority of the surface of the horizontal portion of the terminal, which leads to high ESL values for the capacitor. Thus, by increasing the coupling surface between the interconnects of the substrate and the terminals of the capacitor, a better performing capacitor (e.g., lower value ESL capacitor) can be implemented in a substrate.

### Exemplary Package Comprising Embedded Capacitor

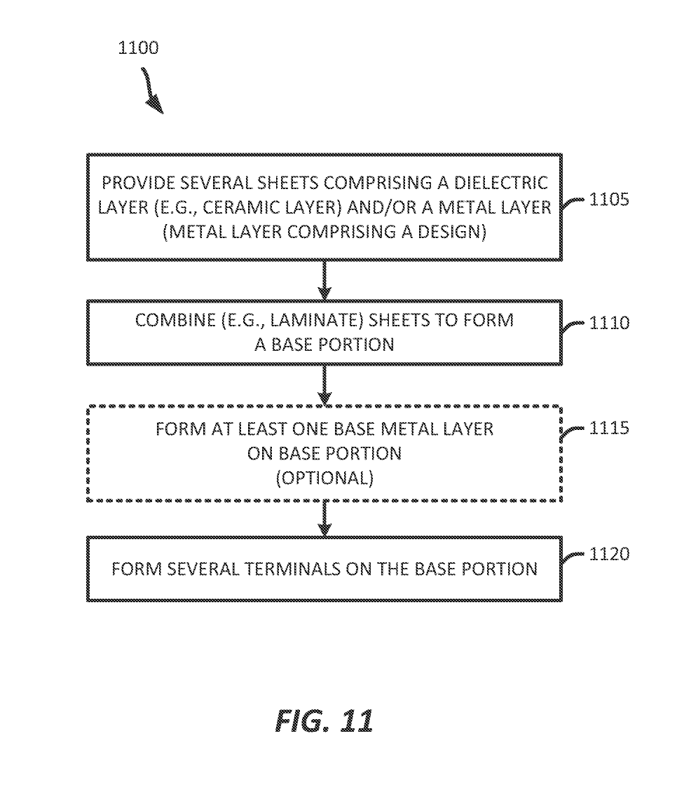

FIG. 7 illustrates an example of a substrate 700 that includes a capacitor 702. The substrate 700 may include a package substrate and/or an interposer. The capacitor 702 may be the capacitors 200 and/or 600, as described above. The capacitor 702 may include the base portion 202, the first base metal layer 601, the second base metal layer 602, the first terminal 210, the second terminal 212, and/or one or more dielectric layers and several metal layers (e.g., metal plates, electrically conductive plates), as previously described above in FIGS. 2-6.

A first die 705 (e.g., first integrated device) is coupled to the substrate 700. The first die 705 is coupled to the substrate 700 through a first set of pillars 707 and a first set of solder balls 709. In some implementations, the first die 705 and the substrate 700 may form an integrated device package.

As shown in FIG. 7, the capacitor 702 is embedded in the substrate 700. The substrate 700 includes a core layer 720, a first dielectric layer 722, a second dielectric layer 724, a third dielectric layer 726, a first solder resist layer 730, and a second solder resist layer 732. The first dielectric layer 722, the second dielectric layer 724, and the third dielectric layer 726 may be a prepeg layer. In some implementations, the substrate 700 is coreless. Thus, in some implementations, the core layer 720 may be replaced with a different dielectric layer (e.g., prepeg layer).

The substrate 700 also includes a first set of interconnects 740, a second set of interconnects 742, a first set of vias 744, a second set of vias 746, a third set of interconnects 750, a fourth set of interconnects 752, a third set of vias 754, a fourth set of vias 756, a first terminal interconnect 760, a second terminal interconnect 762, a first interconnect 764, a second interconnect 766, a first set of pads 780, and a second set of pads 782. The set of interconnects (e.g., the set of interconnects 740, 742, 750, 752) may include traces and pads.

The capacitor 702 is located inside a cavity of the core layer 720. The capacitor 702 is encapsulated by the first dielectric layer 722. In some implementations, the core layer 720 comprises a first thickness, and the capacitor 702 comprises a second thickness that is about the same or less than the first thickness of the core layer 720. In some implementations, the core layer 720 has a thickness of about 0.1 millimeter (mm) or less. As previously mentioned above, the core layer 720 may be replaced by a prepeg layer.

The first terminal interconnect 760 is coupled to a first terminal of the capacitor 702, and the second terminal interconnect 762 is coupled to a second terminal of the capacitor 702. The first terminal of the capacitor 702 is substantially coupled (e.g., majority or more of horizontal portion of the first terminal is directly coupled) to the first terminal interconnect 760. The second terminal of the capacitor 702 is substantially coupled (e.g., majority or more of horizontal portion of the second terminal is directly coupled) to the second terminal interconnect 762. The first terminal interconnect 760 and the second terminal interconnect 762 are located in the dielectric layer 722. The first interconnect 764 is coupled to the first terminal interconnect 760. The second interconnect 766 is coupled to the second terminal interconnect 762. The first interconnect 764 is located in the dielectric layer 724. The second interconnect 766 is located in the dielectric layer 726.

The first set of interconnects 740, the second set of interconnects 742, the first set of vias 744, and the second set of vias 746 are located in the dielectric layer 722. The third set of interconnects 750 and the third set of vias 754 is located in the dielectric layer 724. The fourth set of interconnects 752 and the fourth set of vias 756 are located in the dielectric layer 726. Portions of the first set of pads 780 are covered by the first solder resist layer 730. Portions of the second set of pads 782 are covered by the second solder resist layer 732. A set of solder balls 790 is coupled to the second set of pads 782.

As previously described above, one advantage of the capacitor 702 is that it can be implemented in a substrate, where the terminals can be directly coupled (e.g., directly connected) to traces and/or pads. Normally, vias are directly coupled to the terminals of the capacitors. However, since the terminals of the capacitors are not located on the same surface of the capacitor, vias are not required to directly couple to the terminals. Vias may still be indirectly coupled to the terminals. By taking away the necessity of vias to be directly coupled to the capacitors, a substrate with an overall smaller dimension (e.g., thinner substrate) may be fabricated. Notwithstanding the above, vias in a substrate may be directly coupled to the terminals of the capacitor 702.

Additionally, when traces or interconnects that are larger than vias are coupled to the terminals of the capacitor, the capacitor has a lower intrinsic equivalent series inductance (ESL) value than a comparably sized capacitor. A lower intrinsic ESL for the capacitor leads to better signal performance, and therefore better device performance. When vias are directly coupled to the terminals, the vias couple to less than a majority of the surface of the horizontal portion of the terminal, which leads to high ESL values for the capacitor. Thus, by increasing the coupling surface between the interconnects of the substrate and the terminals of the capacitor, a better performing capacitor (e.g., lower value ESL capacitor) can be implemented in a substrate.

### Exemplary Package Comprising Embedded Capacitor

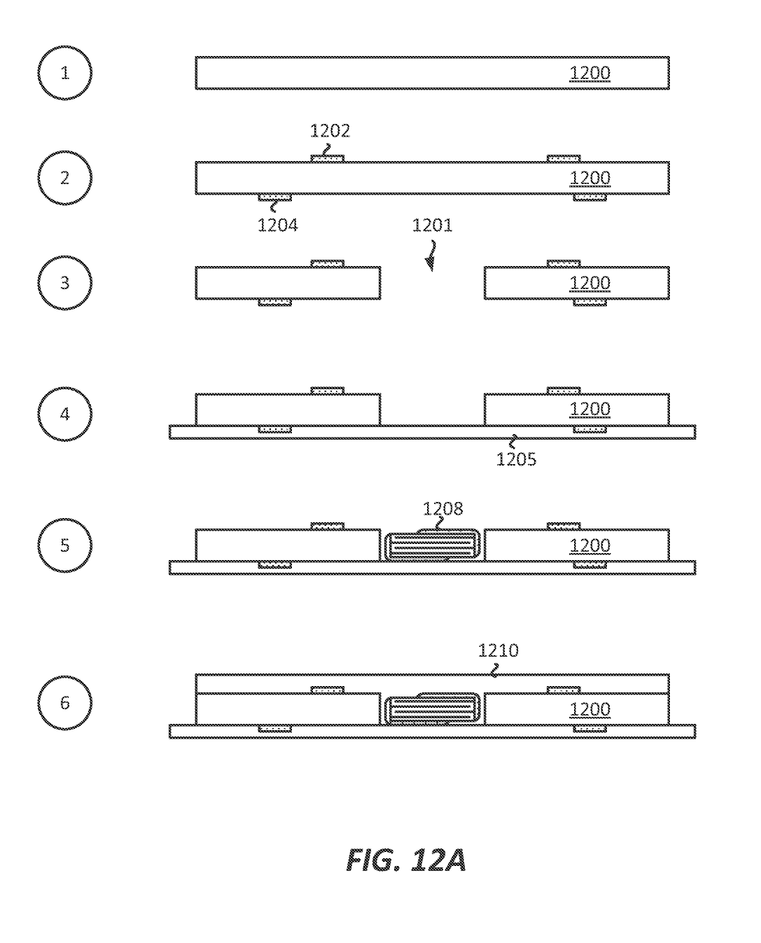

FIG. 8 illustrates an example of a substrate 800 that includes a capacitor 702. The substrate 800 may include a package substrate and/or an interposer. The capacitor 702 may be the capacitors 200 and/or 600, as described above. The capacitor 702 may include the base portion 202, the first base metal layer 601, the second base metal layer 602, the first terminal 210, the second terminal 212, and/or one or more dielectric layers and several metal layers (e.g., metal plates, electrically conductive plates), as previously described above in FIGS. 2-6.

The first die 705 (e.g., first integrated device) is coupled to the substrate 800. The first die 705 is coupled to the substrate 700 through the first set of pillars 707 and the first set of solder balls 709. In some implementations, the first die 705 and the substrate 800 may form an integrated device package.

As shown in FIG. 8, the capacitor 702 is embedded in the substrate 800. The substrate 800 includes the core layer 720, the first dielectric layer 722, the second dielectric layer 724, the third dielectric layer 726, the first solder resist layer 730, and the second solder resist layer 732. The first dielectric layer 722, the second dielectric layer 724, and the third dielectric layer 726 may be a prepeg layer. In some implementations, the substrate 800 is coreless. Thus, in some implementations, the core layer 720 may be replaced with a different dielectric layer (e.g., prepeg layer).

The substrate 800 also includes the first set of interconnects 740, the second set of interconnects 742, the first set of vias 744, the second set of vias 746, the third set of interconnects 750, the fourth set of interconnects 752, the third set of vias 754, the fourth set of vias 756, the first set of pads 780, and a second set of pads 782, as previously described in FIG. 7. The set of interconnects (e.g., the set of interconnects 740, 742, 750, 752) may include traces and pads. The substrate 800 also includes a first terminal interconnect 802, a first via 804, a first interconnect 806, a second terminal interconnect 812, a second via 814, and a second interconnect 816.

The capacitor 702 is located inside a cavity of the core layer 720. The capacitor 702 is encapsulated by the first dielectric layer 722. In some implementations, the core layer 720 comprises a first thickness, and the capacitor 702 comprises a second thickness that is about the same or less than the first thickness of the core layer 720. In some implementations, the core layer 720 has a thickness of about 0.1 millimeter (mm) or less. As previously mentioned above, the core layer 720 may be replaced by a prepeg layer.

The first terminal interconnect 802 is coupled to a first terminal of the capacitor 702, and the second terminal interconnect 812 is coupled to a second terminal of the capacitor 702. The first terminal interconnect 802 is substantially coupled (e.g., majority or more) to the first terminal of the capacitor 702. The second terminal interconnect 812 is substantially coupled (e.g., majority or more) to the second terminal of the capacitor 702. The first via 804 is coupled to the first terminal interconnect 802. The second via 814 is coupled to the second terminal interconnect 812. The first terminal interconnect 802, the second terminal interconnect 812, the first via 804, and the second via 814 are located in the dielectric layer 722. The first interconnect 806 is located in the dielectric layer 724. The first interconnect 806 is coupled to the first via 804. The second interconnect 816 is located in the dielectric layer 726. The second interconnect 816 is coupled to the second via 814.

As previously described above, one advantage of the capacitor 702 is that it can be implemented in a substrate, where the terminals can be directly coupled (e.g., directly connected) to traces and/or pads. Normally, vias are directly coupled to the terminals of the capacitors. However, since the terminals of the capacitors are not located on the same surface of the capacitor, vias are not required to directly couple to the terminals. Vias may still be indirectly coupled to the terminals. By taking away the necessity of vias to be directly coupled to the capacitors, a substrate with an overall smaller dimension (e.g., thinner substrate) may be fabricated. Notwithstanding the above, vias in a substrate may be directly coupled to the terminals of the capacitor 702.

Additionally, when traces or interconnects that are larger than vias are coupled to the terminals of the capacitor, the capacitor has a lower intrinsic equivalent series inductance (ESL) value than a comparably sized capacitor. A lower intrinsic ESL for the capacitor leads to better signal performance, and therefore better device performance. When vias are directly coupled to the terminals, the vias couple to less than a majority of the surface of the horizontal portion of the terminal, which leads to high ESL values for the capacitor. Thus, by increasing the coupling surface between the interconnects of the substrate and the terminals of the capacitor, a better performing capacitor (e.g., lower value ESL capacitor) can be implemented in a substrate.

### Exemplary Sequence for Providing/Fabricating a Capacitor

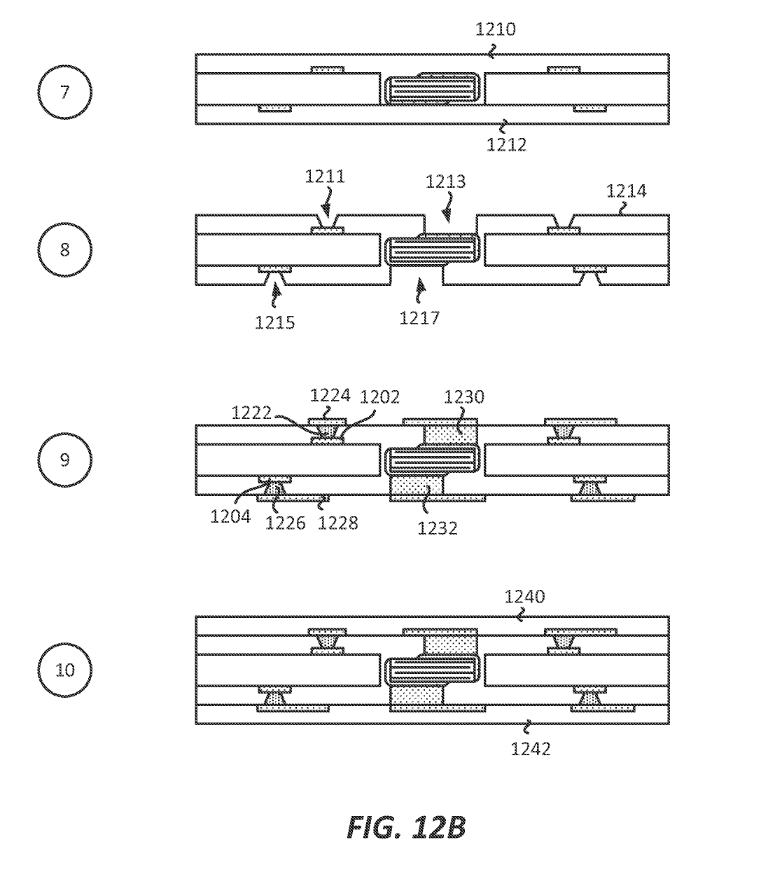

In some implementations, providing/fabricating a capacitor includes several processes. FIG. 9 illustrates an exemplary sequence for providing/fabricating a capacitor. In some implementations, the sequence of FIG. 9 may be used to provide/fabricate the capacitor of FIGS. 2-5 and/or other capacitors in the present disclosure. However, for the purpose of simplification, FIG. 9 will be described in the context of providing/fabricating the capacitor of FIGS. 2-5.

It should be noted that the sequence of FIG. 9 may combine one or more stages in order to simplify and/or clarify the sequence for providing a capacitor. In some implementations, the order of the processes may be changed or modified.

Stage 1 illustrates a state after several sheets (e.g., sheets 902-906) are provided. Some of the sheets include a dielectric layer (e.g., ceramic layer) and a metal layer. Different sheets may include a metal layer with a different pattern design. In some implementations, the metal layer is formed on the dielectric layer using a screen printing process. Examples of sheets are illustrated and described in FIGS. 4-5.

Stage 2 illustrates a state after the several sheets (e.g., sheets 902-906) are combined (e.g., laminated together) to form a base portion 910. The base portion 910 includes a dielectric layer 912 and several metal layers (e.g., several metal plates, several conducting layers). In some implementations, the dielectric layer 912 is a combination of some or all of the dielectric layers of the sheets 902-906.

Stage 3 illustrates a state after a first terminal 920 and a second terminal 922 are formed on the base portion 910. In some implementations, a plating process is used to form the terminals on the base portion 910. In some implementations, each terminal may include one or more conductive layers (e.g., one or more metal layers). In some implementations, stage 3 illustrates a capacitor 930 that includes the base portion 910, the first terminal 920, and the second terminal 922. In some implementations, the capacitor 930 is similar or identical to the capacitor 200 as previously described above.

### Exemplary Sequence for Providing/Fabricating a Capacitor

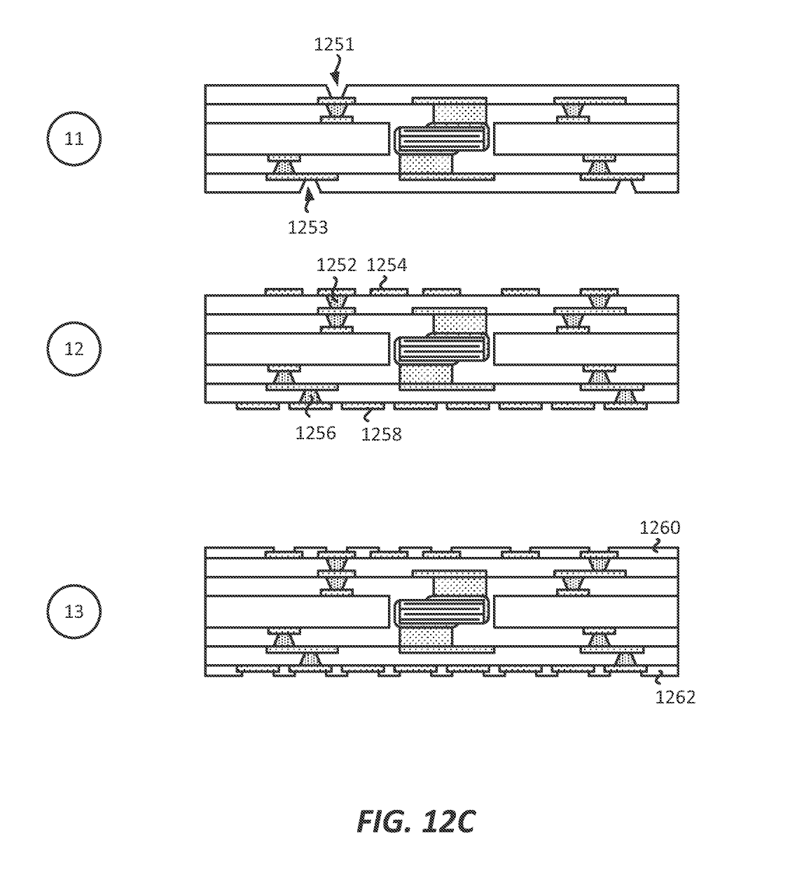

In some implementations, providing/fabricating a capacitor includes several processes. FIG. 10 illustrates an exemplary sequence for providing/fabricating a capacitor. In some implementations, the sequence of FIG. 10 may be used to provide/fabricate the capacitor of FIG. 6 and/or other capacitors in the present disclosure. However, for the purpose of simplification, FIG. 10 will be described in the context of providing/fabricating the capacitor of FIG. 6.

It should be noted that the sequence of FIG. 10 may combine one or more stages in order to simplify and/or clarify the sequence for providing a capacitor. In some implementations, the order of the processes may be changed or modified.

Stage 1 illustrates a state after several sheets (e.g., sheets 1002-1006) are provided. Some of the sheets include a dielectric layer (e.g., ceramic layer) and a metal layer. Different sheets may include a metal layer with a different pattern design. In some implementations, the metal layer is formed on the dielectric layer using a screen printing process. Examples of sheets are illustrated and described in FIGS. 4-5.

Stage 2 illustrates a state after the several sheets (e.g., sheets 1002-1006) are combined (e.g., laminated together) to form a base portion 1010. The base portion 1010 includes a dielectric layer 1012 and several metal layers (e.g., several metal plates, several conducting layers). In some implementations, the dielectric layer 1012 is a combination of some or all of the dielectric layers of the sheets 1002-1006.

Stage 3 illustrates a state after a first base metal layer 1020 is provided (e.g., formed) on a first surface (e.g., bottom surface) of the base portion 1010, a second base metal layer 1022 is provided (e.g., formed) on a second surface (e.g., top surface) of the base portion 1010. In some implementations, the first base metal layer 1020 and the second base metal layer 1022 are formed by a plating process.

Stage 4 illustrates a state after a first terminal 1030 and a second terminal 1032 are formed on the base portion 1010. Specifically, the first terminal 1030 is formed in the first base metal layer 1020, and the second terminal 1032 is formed in the second base metal layer 1022. In some implementations, a plating process is used to form the terminals on the base portion 1010. In some implementations, each terminal may include one or more conductive layers (e.g., one or more metal layers). In some implementations, stage 4 illustrates a capacitor 1040 that includes the base portion 1010, the first terminal 1030, and the second terminal 1032. In some implementations, the capacitor 1040 is similar or identical to the capacitor 600 as previously described above.

### Exemplary Method for Providing/Fabricating a Capacitor

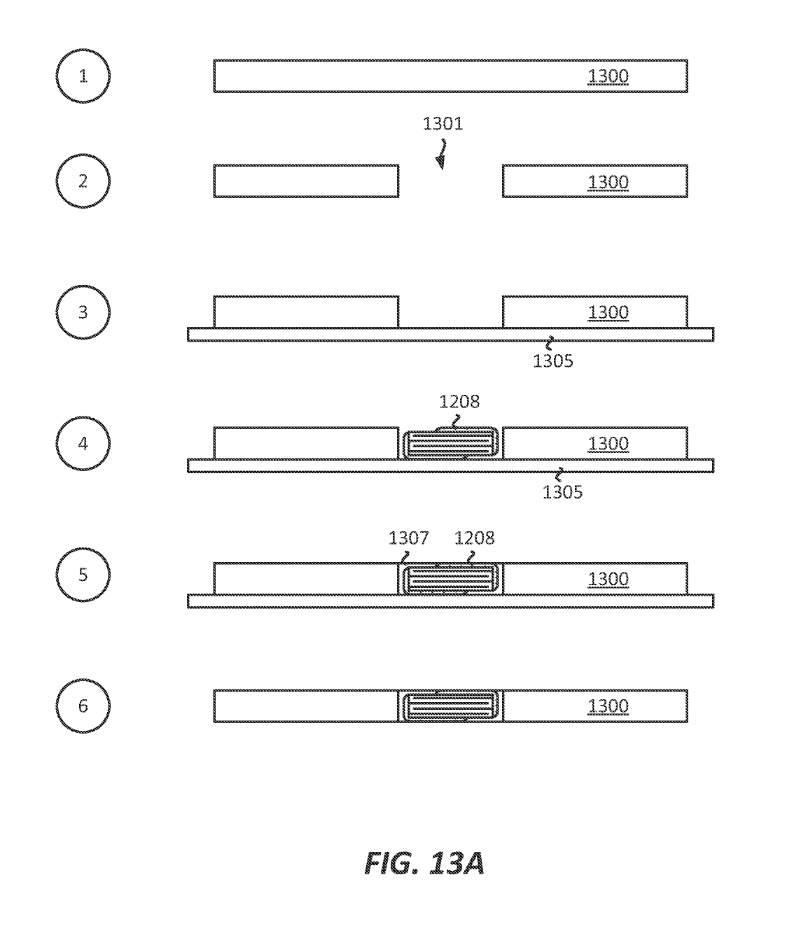

FIG. 11 illustrates an exemplary flow diagram of a method 1100 for providing/fabricating a capacitor. In some implementations, the method of FIG. 11 may be used to provide/fabricate the capacitor of FIGS. 2-6 and/or other capacitors in the present disclosure.

It should be noted that the flow diagram of FIG. 11 may combine one or more step and/or processes in order to simplify and/or clarify the method for providing an integrated device package. In some implementations, the order of the processes may be changed or modified.

The method provides (at 1105) several sheets (e.g., sheets 902-906). Some of the sheets include a dielectric layer (e.g., ceramic layer) and a metal layer. Different sheets may include a metal layer with a different pattern design. In some implementations, the metal layer is formed on the dielectric layer using a screen printing process.

The method combines (at 1110) the sheets (e.g., sheets 902-906) to form a base portion (e.g., base portion 1910). The base portion includes a dielectric layer and several metal layers (e.g., several metal plates, several conducting layers). For example, the dielectric layer is a combination of some or all of the dielectric layers of the sheets 902-906.

The method may optionally form (at 1115) at least one base metal layer on the base portion. For example, a first base metal layer (e.g., base metal layer 1020) may be formed on a first surface (e.g., bottom surface) of the base portion, and a second base metal layer (e.g., base metal layer 1022) may be formed on a second surface (e.g., top surface) of the base portion. In some implementations, the base metal layers are formed by a plating process.

The method forms (at 1120) several terminals (e.g., terminals 920, 922) on the base portion. The terminals may be formed over the base metal layer. In some implementations, a plating process is used to form the terminals on the base portion. In some implementations, each terminal may include one or more conductive layers (e.g., one or more metal layers).

### Exemplary Sequence for Providing/Fabricating a Substrate Comprising a Capacitor

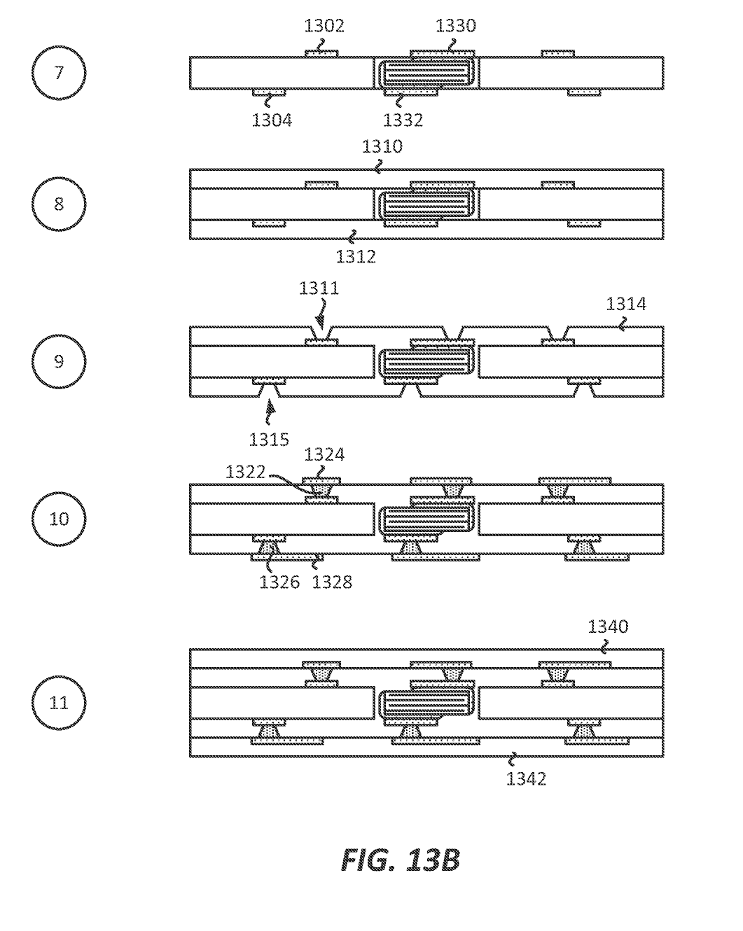

In some implementations, providing/fabricating a substrate comprising a capacitor includes several processes. FIG. 12 (which includes FIGS. 12A-12C) illustrates an exemplary sequence for providing/fabricating a substrate comprising a capacitor. In some implementations, the sequence of FIGS. 12A-12C may be used to provide/fabricate the substrate of FIGS. 7-8 and/or other substrates in the present disclosure. However, for the purpose of simplification, FIGS. 12A-12C will be described in the context of providing/fabricating the substrate of FIG. 7.

It should be noted that the sequence of FIGS. 12A-12C may combine one or more stages in order to simplify and/or clarify the sequence for providing a substrate. In some implementations, the order of the processes may be changed or modified.

Stage 1 of FIG. 12A, illustrates a state after a core layer 1200 is provided. The core layer 1200 may be a dielectric layer and/or a substrate (e.g., silicon substrate).

Stage 2 illustrates a state after a first set of interconnects 1202 and a second set of interconnects 1204 are formed in the core layer 1200. Specifically, the first set of interconnects 1202 is formed on a first surface of the core layer 1200, and the second set of interconnects 1204 is formed on a second surface of the core layer 1200.

Stage 3 illustrates a state after a cavity 1201 is formed in the core layer 1200. Different implementations may use different processes to form the cavity 1201. In some implementations, the cavity 1201 is formed by using a laser and/or photo etching process.

Stage 4 illustrates a state after the core layer 1200 is coupled to a carrier 1205. In some implementations, the carrier 1205 is an adhesive carrier.

Stage 5 illustrates a state after a capacitor 1208 is positioned on the carrier 1205 in the cavity 1201 of the core layer 1200. Different implementations may use different capacitors. In some implementations, the capacitor 1208 is identical or similar to the capacitors 200 or 600 as described above.

Stage 6 illustrates a state after a first dielectric layer 1210 is formed on a first surface (e.g., top surface) of the core layer 1200 and the capacitor 1208. The first dielectric layer 1210 fills the cavity 1201 and encapsulates the capacitor 1208.

Stage 7 of FIG. 12B, illustrates a state after the carrier 1205 is removed, and a second dielectric layer 1212 is formed on a second surface (e.g., bottom surface) of the core layer 1200. The first dielectric layer 1210 and the second dielectric layer 1212 may be a single dielectric layer 1214. In some implementations, the dielectric layers 1210, 1212 and/or 1214 is a photo-etchable dielectric layer (e.g., can be etched by using a photo lithography process).

Stage 8 illustrates a state after a first cavity 1211, a second cavity 1213, a third cavity 1215, and a fourth cavity 1217 are formed in the dielectric layer 1214. In some implementations, the dielectric layer 1214 is a combination of the first dielectric layer 1210 and the second dielectric layer 1212. Different implementations may use different processes to form the cavities 1211, 1213, 1215, and 1217. In some implementations, the cavities 1211, 1213, 1215 and 1217 are formed by using a laser and/or photo etching process. The cavities 1213 and 1217 are formed over the terminals of the capacitor 1208.

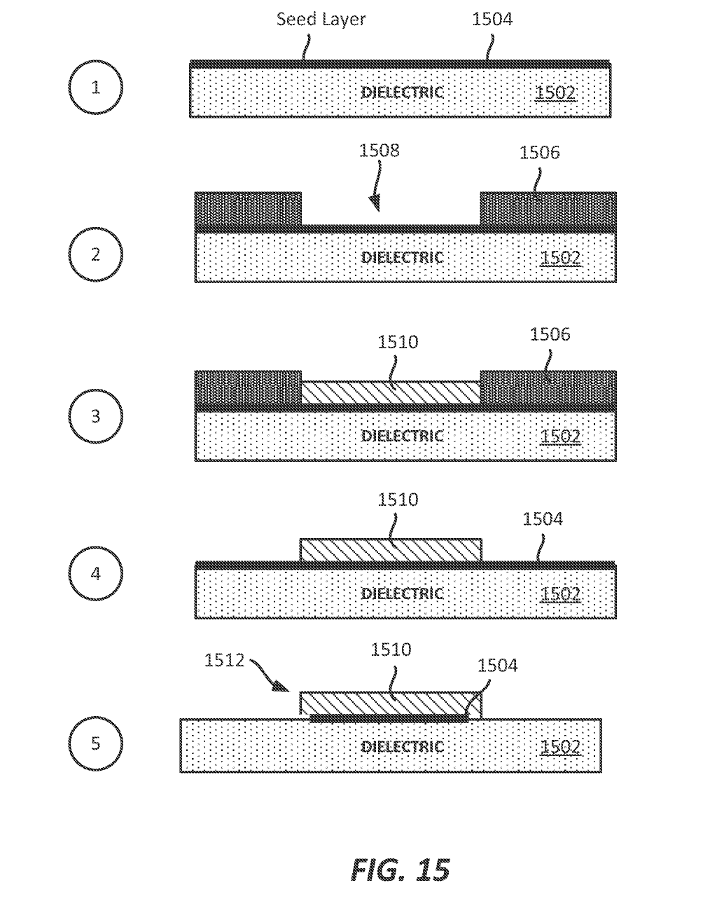

Stage 9 illustrates a state after a first set of vias 1222, a first set of interconnects 1224 (e.g., traces, pads), a second set of vias 1226, a second set of interconnects 1228 (e.g., traces, pads), a first terminal interconnect 1230, and a second terminal interconnect 1232 are formed in/on the dielectric layer 1214. Different implementations may use different processes to form the interconnects and/or vias. Various examples of forming interconnects (e.g., vias, traces, pads) are further described below in FIGS. 15-18.

Stage 10 illustrates a state after a third dielectric layer 1240 and a fourth dielectric layer 1242 are formed. The third dielectric layer 1240 is formed over the first set of interconnects 1224. The fourth dielectric layer 1242 is formed over the second set of interconnects 1228.

Stage 11 of FIG. 12C illustrates a state after a cavity 1251 is formed in the third dielectric layer 1240, and a cavity 1253 is formed in the fourth dielectric layer 1242. Different implementations may use different processes to form the cavities 1251 and 1253. In some implementations, the cavities 1251 and 1253 are formed by using a laser and/or photo etching process.

Stage 12 illustrates a state after a third set of vias 1252 and a third set of interconnects 1254 (e.g., traces, pads) are formed in/on the third dielectric layer 1240; and a fourth set of vias 1256 and a fourth set of interconnects 1258 (e.g., traces, pads) are formed in/on the fourth dielectric layer 1242. Different implementations may use different processes to form the interconnects and/or vias. Various examples of forming interconnects (e.g., vias, traces, pads) are further described below in FIGS. 15-18.

Stage 13 illustrates a state after a first solder resist layer 1260 and a second solder resist layer 1262 are formed. As shown, the first solder resist layer 1260 is formed over the third dielectric layer 1240, and the second solder resist layer 1262 is formed over the fourth dielectric layer 1242.

### Exemplary Sequence for Providing/Fabricating a Substrate Comprising a Capacitor

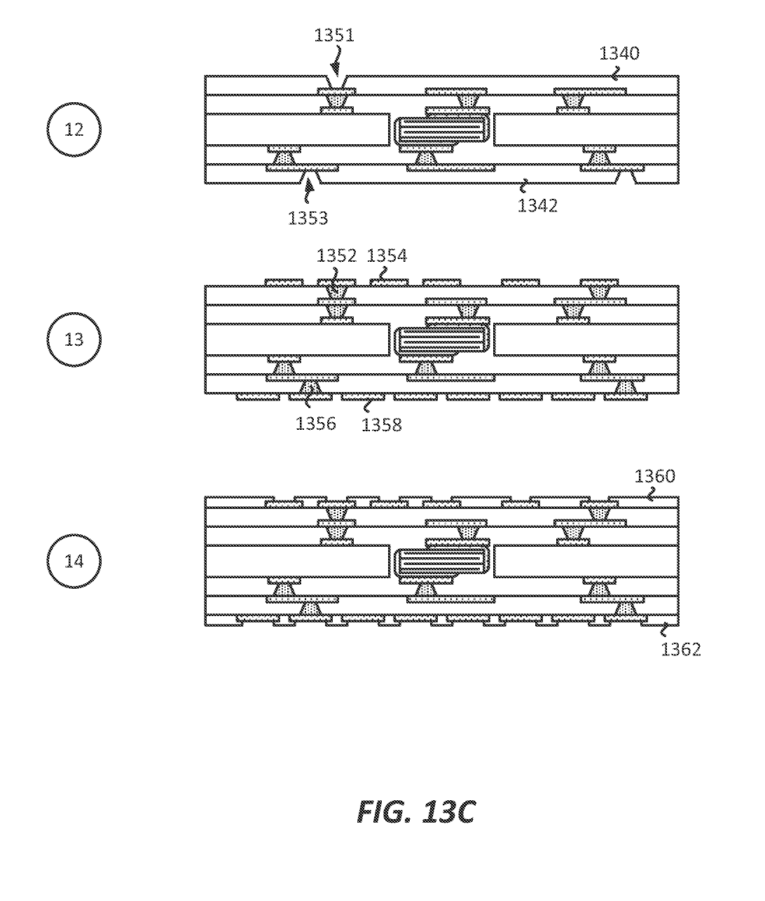

In some implementations, providing/fabricating a substrate comprising a capacitor includes several processes. FIG. 13 (which includes FIGS. 13A-13C) illustrates an exemplary sequence for providing/fabricating a substrate comprising a capacitor. In some implementations, the sequence of FIGS. 13A-13C may be used to provide/fabricate the substrate of FIGS. 7-8 and/or other substrates in the present disclosure. However, for the purpose of simplification, FIGS. 13A-13C will be described in the context of providing/fabricating the substrate of FIG. 8.

It should be noted that the sequence of FIGS. 13A-13C may combine one or more stages in order to simplify and/or clarify the sequence for providing a substrate. In some implementations, the order of the processes may be changed or modified.

Stage 1 of FIG. 13A, illustrates a state after a core layer 1300 is provided. The core layer 1300 may be a dielectric layer and/or a substrate (e.g., silicon substrate).

Stage 2 illustrates a state after a cavity 1301 is formed in the core layer 1300. Different implementations may use different processes to form the cavity 1301. In some implementations, the cavity 1301 is formed by using a laser and/or photo etching process.

Stage 3 illustrates a state after the core layer 1300 is coupled to a carrier 1305. In some implementations, the carrier 1305 is an adhesive carrier.

Stage 4 illustrates a state after a capacitor 1208 is positioned on the carrier 1305 in the cavity 1301 of the core layer 1300. Different implementations may use different capacitors. In some implementations, the capacitor 1208 is identical or similar to the capacitors 200 or 600 as described above.

Stage 5 illustrates a state after a dielectric layer 1307 is formed in the cavity 1301 of the core layer 1300. The dielectric layer 1307 may encapsulate the capacitor 1208.

Stage 6 illustrates a state after the carrier 1305 is removed, leaving behind the core layer 1300, the capacitor 1308, and the dielectric layer 1307.

Stage 7, as shown in FIG. 13B, illustrates a state after a first set of interconnects 1302 and a second set of interconnects 1304 are formed in the core layer 1300, and a first terminal interconnect 1330 and a second terminal interconnect 1332 are formed on terminals of the capacitor 1208. Specifically, the first set of interconnects 1302 is formed on a first surface of the core layer 1300, and the second set of interconnects 1304 is formed on a second surface of the core layer 1300.

Stage 8 illustrates a state after a first dielectric layer 1310 is formed on a first surface (e.g., top surface) of the core layer 1300, and a second dielectric layer 1312 is formed on a second surface (e.g., bottom surface) of the core layer 1300. In some implementations, the dielectric layers 1307, 1310, and 1312 form a dielectric layer 1314. In some implementations, the dielectric layers 1307, 1310, 1312 and/or 1314 is a photo-etchable dielectric layer (e.g., can be etched by using a photo lithography process).

Stage 9 illustrates a state after a cavity 1311 and a cavity 1315 are formed in the dielectric layer 1314. Different implementations may use different processes to form the cavities 1311 and 1315. In some implementations, the cavities 1311 and 1315 are formed by using a laser and/or photo etching process.

Stage 10 illustrates a state after a first set of vias 1322, a first set of interconnects 1324 (e.g., traces, pads), a second set of vias 1326, and a second set of interconnects 1328 (e.g., traces, pads) are formed in/on the dielectric layer 1314. Different implementations may use different processes to form the interconnects and/or vias. Various examples of forming interconnects (e.g., vias, traces, pads) are further described below in FIGS. 15-18.

Stage 11 illustrates a state after a third dielectric layer 1340 and a fourth dielectric layer 1342 are formed. The third dielectric layer 1340 is formed over the first set of interconnects 1324. The fourth dielectric layer 1342 is formed over the second set of interconnects 1328.

Stage 12 of FIG. 13C illustrates a state after a cavity 1351 is formed in the third dielectric layer 1340, and a cavity 1353 is formed in the fourth dielectric layer 1342. Different implementations may use different processes to form the cavities 1351 and 1353. In some implementations, the cavities 1351 and 1353 are formed by using a laser and/or photo etching process.

Stage 13 illustrates a state after a third set of vias 1352 and a third set of interconnects 1354 (e.g., traces, pads) are formed in/on the third dielectric layer 1340, and a fourth set of vias 1356 and a fourth set of interconnects 1358 (e.g., traces, pads) are formed in/on the fourth dielectric layer 1342. Different implementations may use different processes to form the interconnects and/or vias. Various examples of forming interconnects (e.g., vias, traces, pads) are further described below in FIGS. 15-18.

Stage 14 illustrates a state after a first solder resist layer 1360 and a second solder resist layer 1362 are formed. As shown, the first solder resist layer 1360 is formed over the third dielectric layer 1340, and the second solder resist layer 1362 is formed over the fourth dielectric layer 1342.

### Exemplary Method for Providing/Fabricating a Substrate Comprising a Capacitor

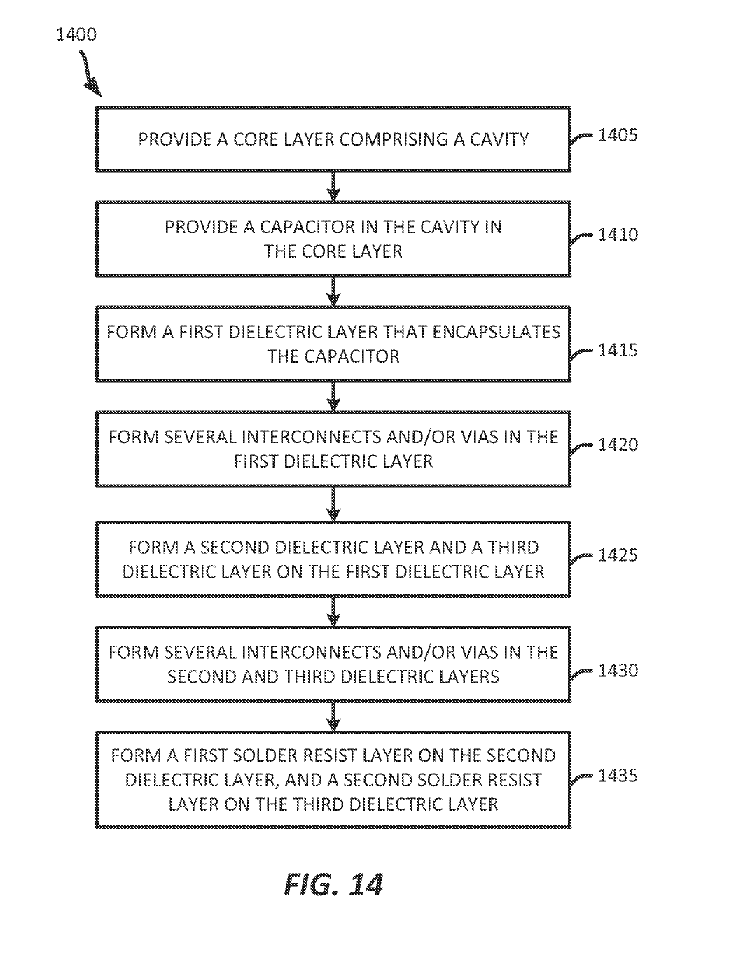

FIG. 14 illustrates an exemplary flow diagram of a method 1400 for providing/fabricating a substrate comprising a capacitor. In some implementations, the method of FIG. 14 may be used to provide/fabricate the substrate comprising a capacitor of FIGS. 7, 8 and/or other substrates in the present disclosure.

It should be noted that the flow diagram of FIG. 14 may combine one or more step and/or processes in order to simplify and/or clarify the method for providing a substrate. In some implementations, the order of the processes may be changed or modified.

The method provides (at 1405) a core layer that includes a cavity. The core layer may be a dielectric layer and/or a substrate (e.g., silicon substrate). In some implementations, providing a core layer that includes a cavity includes forming a core layer, forming a cavity in the core layer and coupling the core layer to a carrier. Different implementations may use different processes to form the cavity. In some implementations, the cavity is formed by using a laser and/or photo etching process (e.g., a photo lithography process).

The method positions (at 1410) a capacitor in the cavity of the core layer. Different implementations may use different capacitors. In some implementations, the capacitor is identical or similar to the capacitors 200 or 600 as described above.

The method forms (at 1415) a first dielectric layer that encapsulates the capacitor. In some implementations, the first dielectric layer may include several dielectric layers.

The method forms (at 1420) several terminal interconnects, interconnects and/or vias in the first dielectric layer. The terminal interconnects may be coupled to terminals in the capacitors. Different implementations may use different processes to form the interconnects and/or vias. Various examples of forming interconnects (e.g., vias, traces, pads) are further described below in FIGS. 15-18.

The method forms (at 1425) a second dielectric layer and a third dielectric layer. The second dielectric layer is formed on a first surface of the first dielectric layer. The third dielectric layer is formed on a second surface of the first dielectric layer.

The method forms (at 1430) several interconnects and/or vias in the second and third dielectric layers. Different implementations may use different processes to form the interconnects and/or vias. Various examples of forming interconnects (e.g., vias, traces, pads) are further described below in FIGS. 15-18.

The method forms (at 1435) a first solder resist layer on the second dielectric layer, and a second solder resist layer on the third dielectric layer.

### Exemplary Semi-Additive Patterning (SAP) Process

Various interconnects (e.g., traces, vias, pads) are described in the present disclosure. These interconnects may be formed in the package substrate and/or the redistribution portion of the integrated device package. In some implementations, these interconnects may includes one or more metal layers. For example, in some implementations, these interconnects may include a first metal seed layer and a second metal layer. The metal layers may be provided (e.g., formed) using different plating processes. Below are detailed examples of interconnects (e.g., traces, vias, pads) with seed layers and how these interconnects may be formed using different plating processes.

Different implementations may use different processes to form and/or fabricate the metal layers (e.g., interconnects, redistribution layer, under bump metallization layer, protrusion). In some implementations, these processes include a semi-additive patterning (SAP) process and a damascene process. These various different processes are further described below.

FIG. 15 illustrates a sequence for forming an interconnect using a semi-additive patterning (SAP) process to provide and/or form an interconnect in one or more dielectric layer(s). As shown in FIG. 15, stage 1 illustrates a state of an integrated device (e.g., substrate) after a dielectric layer 1502 is provided (e.g., formed). In some implementations, stage 1 illustrates that the dielectric layer 1502 includes a first metal layer 1504. The first metal layer 1504 is a seed layer in some implementations. In some implementations, the first metal layer 1504 may be provided (e.g., formed) on the dielectric layer 1502 after the dielectric layer 1502 is provided (e.g., received or formed). Stage 1 illustrates that the first metal layer 1504 is provided (e.g., formed) on a first surface of the dielectric layer 1502. In some implementations, the first metal layer 1504 is provided by using a deposition process (e.g., PVD, CVD, plating process).

Stage 2 illustrates a state of the integrated device after a photo resist layer 1506 (e.g., photo develop resist layer) is selectively provided (e.g., formed) on the first metal layer 1504. In some implementations, selectively providing the resist layer 1506 includes providing a first resist layer 1506 on the first metal layer 1504 and selectively removing portions of the resist layer 1506 by developing (e.g., using a development process). Stage 2 illustrates that the resist layer 1506 is provided such that a cavity 1508 is formed.

Stage 3 illustrates a state of the integrated device after a second metal layer 1510 is formed in the cavity 1508. In some implementations, the second metal layer 1510 is formed over an exposed portion of the first metal layer 1504. In some implementations, the second metal layer 1510 is provided by using a deposition process (e.g., plating process).

Stage 4 illustrates a state of the integrated device after the resist layer 1506 is removed. Different implementations may use different processes for removing the resist layer 1506.

Stage 5 illustrates a state of the integrated device after portions of the first metal layer 1504 are selectively removed. In some implementations, one or more portions of the first metal layer 1504 that is not covered by the second metal layer 1510 is removed. As shown in stage 5, the remaining first metal layer 1504 and the second metal layer 1510 may form and/or define an interconnect 1512 (e.g., trace, vias, pads) in an integrated device and/or a substrate. In some implementations, the first metal layer 1504 is removed such that a dimension (e.g., length, width) of the first metal layer 1504 underneath the second metal layer 1510 is about the same or smaller than a dimension (e.g., length, width) of the second metal layer 1510, which can result in an undercut, as shown at stage 5 of FIG. 15. In some implementations, the above mentioned processes may be iterated several times to provide and/or form several interconnects in one or more dielectric layers of an integrated device and/or substrate.

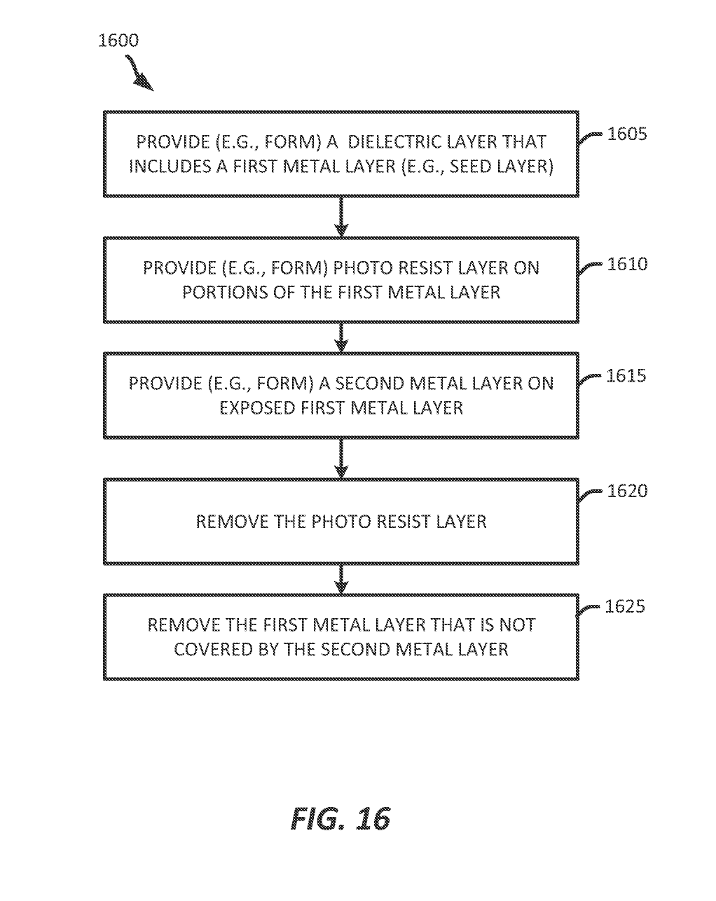

FIG. 16 illustrates a flow diagram for a method for using a (SAP) process to provide and/or form an interconnect in one or more dielectric layer(s). The method provides (at 1605) a dielectric layer (e.g., dielectric layer 1502). In some implementations, providing the dielectric layer includes forming the dielectric layer. In some implementations, providing the dielectric layer includes forming a first metal layer (e.g., first metal layer 1504). The first metal layer is a seed layer in some implementations. In some implementations, the first metal layer may be provided (e.g., formed) on the dielectric layer after the dielectric layer is provided (e.g., received or formed). In some implementations, the first metal layer is provided by using a deposition process (e.g., physical vapor deposition (PVD) or plating process).

The method selectively provides (at 1610) a photo resist layer (e.g., a photo develop resist layer 1506) on the first metal layer. In some implementations, selectively providing the resist layer includes providing a first resist layer on the first metal layer and selectively removing portions of the resist layer (which provides one or more cavities).

The method then provides (at 1615) a second metal layer (e.g., second metal layer 1510) in the cavity of the photo resist layer. In some implementations, the second metal layer is formed over an exposed portion of the first metal layer. In some implementations, the second metal layer is provided by using a deposition process (e.g., plating process).

The method further removes (at 1620) the resist layer. Different implementations may use different processes for removing the resist layer. The method also selectively removes (at 1625) portions of the first metal layer. In some implementations, one or more portions of the first metal layer that is not covered by the second metal layer are removed. In some implementations, any remaining first metal layer and second metal layer may form and/or define one or more interconnects (e.g., trace, vias, pads) in an integrated device and/or a substrate. In some implementations, the above mentioned method may be iterated several times to provide and/or form several interconnects in one or more dielectric layers of an integrated device and/or substrate.

### Exemplary Damascene Process

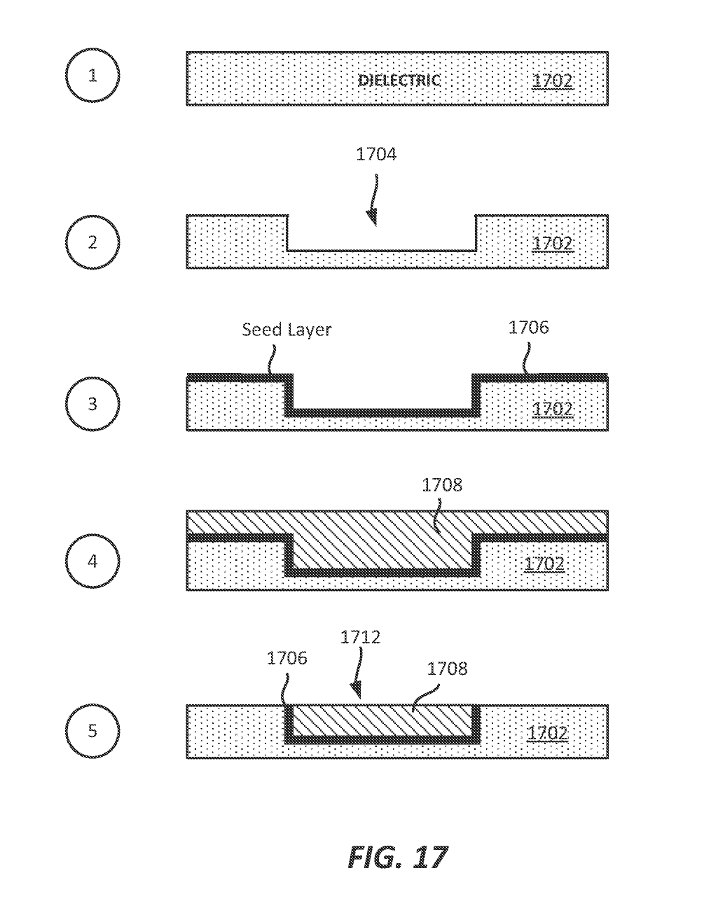

FIG. 17 illustrates a sequence for forming an interconnect using a damascene process to provide and/or form an interconnect in a dielectric layer. As shown in FIG. 17, stage 1 illustrates a state of an integrated device after a dielectric layer 1702 is provided (e.g., formed). In some implementations, the dielectric layer 1702 is an inorganic layer (e.g., inorganic film).

Stage 2 illustrates a state of an integrated device after a cavity 1704 is formed in the dielectric layer 1702. Different implementations may use different processes for providing the cavity 1704 in the dielectric layer 1702.

Stage 3 illustrates a state of an integrated device after a first metal layer 1706 is provided on the dielectric layer 1702. As shown in stage 3, the first metal layer 1706 provided on a first surface of the dielectric layer 1702. The first metal layer 1706 is provided on the dielectric layer 1702 such that the first metal layer 1706 takes the contour of the dielectric layer 1702 including the contour of the cavity 1704. The first metal layer 1706 is a seed layer in some implementations. In some implementations, the first metal layer 1706 is provided by using a deposition process (e.g., physical vapor deposition (PVD), Chemical Vapor Deposition (CVD) or plating process).

Stage 4 illustrates a state of the integrated device after a second metal layer 1708 is formed in the cavity 1704 and a surface of the dielectric layer 1702. In some implementations, the second metal layer 1708 is formed over an exposed portion of the first metal layer 1706. In some implementations, the second metal layer 1708 is provided by using a deposition process (e.g., plating process).

Stage 5 illustrates a state of the integrated device after the portions of the second metal layer 1708 and portions of the first metal layer 1706 are removed. Different implementations may use different processes for removing the second metal layer 1708 and the first metal layer 1706. In some implementations, a chemical mechanical planarization (CMP) process is used to remove portions of the second metal layer 1708 and portions of the first metal layer 1706. As shown in stage 5, the remaining first metal layer 1706 and the second metal layer 1708 may form and/or define an interconnect 1712 (e.g., trace, vias, pads) in an integrated device and/or a substrate. As shown in stage 5, the interconnect 1712 is formed in such a way that the first metal layer 1706 is formed on the base portion and the side portion(s) of the second metal layer 1710. In some implementations, the cavity 1704 may include a combination of trenches and/or holes in two levels of dielectrics so that via and interconnects (e.g., metal traces) may be formed in a single deposition step, In some implementations, the above mentioned processes may be iterated several times to provide and/or form several interconnects in one or more dielectric layers of an integrated device and/or substrate.

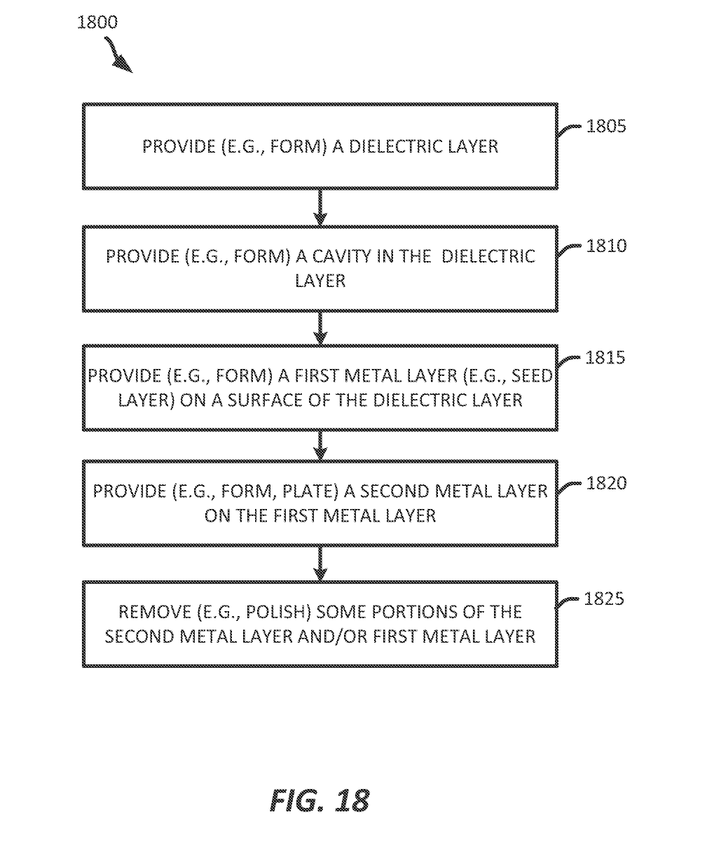

FIG. 18 illustrates a flow diagram of a method 1800 for forming an interconnect using a damascene process to provide and/or form an interconnect in a dielectric layer. The method provides (at 1805) a dielectric layer (e.g., dielectric layer 1702). In some implementations, providing a dielectric layer includes forming a dielectric layer. In some implementations, providing a dielectric layer includes receiving a dielectric layer from a supplier. In some implementations, the dielectric layer is an inorganic layer (e.g., inorganic film).

The method forms (at 1810) at least one cavity (e.g., cavity 1704) in the dielectric layer. Different implementations may use different processes for providing the cavity in the dielectric layer.

The method provides (at 1815) a first metal layer (e.g., first metal layer 1706) on the dielectric layer. In some implementations, the first metal layer is provided (e.g., formed) on a first surface of the dielectric later. In some implementations, the first metal layer is provided on the dielectric layer such that the first metal layer takes the contour of the dielectric layer including the contour of the cavity. The first metal layer is a seed layer in some implementations. In some implementations, the first metal layer 1706 is provided by using a deposition process (e.g., PVD, CVD or plating process).

The method provides (at 1820) a second metal layer (e.g., second metal layer 1708) in the cavity and a surface of the dielectric layer. In some implementations, the second metal layer is formed over an exposed portion of the first metal layer. In some implementations, the second metal layer is provided by using a deposition process (e.g., plating process). In some implementations, the second metal layer is similar or identical to the first metal layer. In some implementations, the second metal layer is different than the first metal layer.

The method then removes (at 1825) portions of the second metal layer and portions of the first metal layer. Different implementations may use different processes for removing the second metal layer and the first metal layer. In some implementations, a chemical mechanical planarization (CMP) process is used to remove portions of the second metal layer and portions of the first metal layer. In some implementations, the remaining first metal layer and the second metal layer may form and/or define an interconnect (e.g., interconnect 1712). In some implementations, an interconnect may include one of at least a trace, a via, and/or a pad) in an integrated device and/or a substrate. In some implementations, the interconnect is formed in such a way that the first metal layer is formed on the base portion and the side portion(s) of the second metal layer. In some implementations, the above mentioned method may be iterated several times to provide and/or form several interconnects in one or more dielectric layers of an integrated device and/or substrate.

### Exemplary Electronic Devices

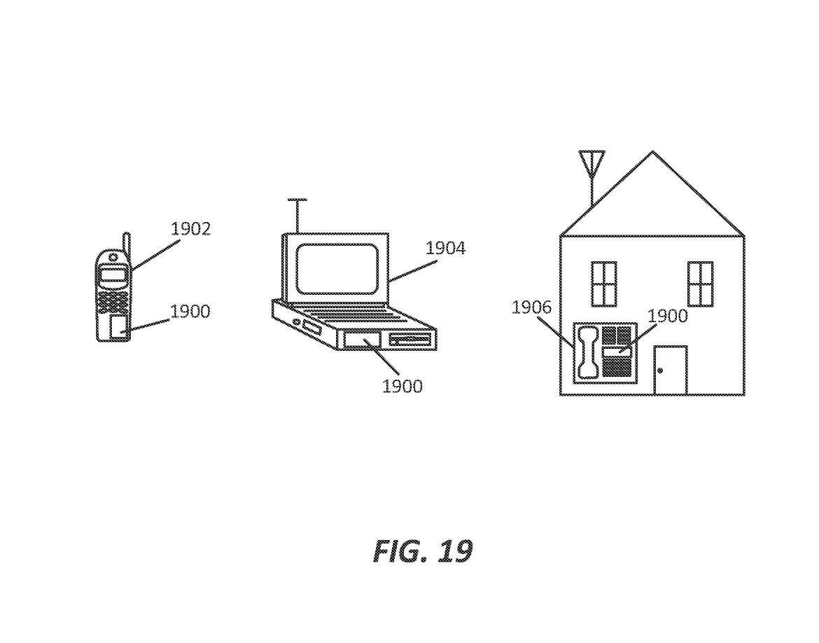

FIG. 19 illustrates various electronic devices that may be integrated with any of the aforementioned integrated device, semiconductor device, integrated circuit, die, interposer, package or package-on-package (PoP). For example, a mobile telephone 1902, a laptop computer 1904, and a fixed location terminal 1906 may include an integrated device 1900 as described herein. The integrated device 1900 may be, for example, any of the integrated circuits, dice, packages, package-on-packages described herein. The devices 1902, 1904, 1906 illustrated in FIG. 19 are merely exemplary. Other electronic devices may also feature the integrated device 1900 including, but not limited to, mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers or any other device that stores or retrieves data or computer instructions, or any combination thereof.

One or more of the components, steps, features, and/or functions illustrated in FIGS. 2, 3, 4, 5, 6, 7, 8, 9, 10, 11, 12A-12C, 13A-13C, 14, 15, 16, 17, 18, and/or 19 may be rearranged and/or combined into a single component, step, feature or function or embodied in several components, steps, or functions. Additional elements, components, steps, and/or functions may also be added without departing from the disclosure. It should also be noted that FIGS. 2, 3, 4, 5, 6, 7, 8, 9, 10, 11, 12A-12C, 13A-13C, 14, 15, 16, 17, 18, and/or 19 and its corresponding description in the present disclosure is not limited to dies and/or ICs. In some implementations, FIGS. 2, 3, 4, 5, 6, 7, 8, 9, 10, 11, 12A-12C, 13A-13C, 14, 15, 16, 17, 18, and/or 19 and its corresponding description may be used to manufacture, create, provide, and/or produce integrated devices.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another-even if they do not directly physically touch each other.

A ‘set’ of objects may include one or more objects. For example, a set of interconnects may include one or more interconnects. A set of vias may include one or more vias. A set of pads may include one or more pads.

Also, it is noted that the embodiments may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A substrate comprising:
a first dielectric layer; and
a capacitor embedded in the first dielectric layer, the capacitor comprising:
a base portion;
a first terminal located on a first surface of the base portion, wherein the first terminal is the only terminal on the first surface of the base portion; and
a second terminal located on a second surface of the base portion, the second surface opposite to the first surface, wherein the second terminal is the only terminal on the second surface of the base portion.

2. The substrate of claim 1, wherein the capacitor further comprises:
a first base metal layer located between the first surface of the base portion and the first terminal; and
a second base metal layer located between the second surface of the base portion and the second terminal.

3. The substrate of claim 1, further comprising:
a first terminal interconnect coupled to the first terminal of the capacitor; and
a second terminal interconnect coupled to the second terminal of the capacitor.

4. The substrate of claim 3, wherein the first terminal interconnect is coupled to the first terminal such that a substantial part of a horizontal portion of the first terminal is in contact with the first terminal interconnect.

5. The substrate of claim 4, wherein the second terminal interconnect is coupled to the second terminal such that a substantial part of a horizontal portion of the second terminal is in contact with the second terminal interconnect.

6. The substrate of claim 3, wherein the first terminal interconnect is coupled to the first terminal such that a majority of a horizontal portion of the first terminal is in contact with the first terminal interconnect.

7. The substrate of claim 1, wherein the capacitor comprises a lateral dimension of about 0.5 millimeter (mm) or less and/or a vertical dimension of about 0.1 millimeter (mm) or less.

8. The substrate of claim 1 further comprising a core layer, the core layer comprising a cavity in which the capacitor is located in, the first dielectric layer formed in the substrate such that the first dielectric layer fills the cavity of the core layer and encapsulates the capacitor.

9. The substrate of claim 8, wherein the core layer comprises a first thickness, and the capacitor comprises a second thickness that is about the same or less than the first thickness.

10. The substrate of claim 1, wherein the substrate includes one of at least a package substrate and/or an interposer.

11. The substrate of claim 1, wherein the substrate is incorporated into at least one of a music player, a video player, an entertainment unit, a navigation device, a communications device, a mobile device, a mobile phone, a smartphone, a personal digital assistant, a fixed location terminal, a tablet computer, and/or a laptop computer.

12. A method for fabricating a substrate, comprising:
forming a first dielectric layer; and
embedding a capacitor in the first dielectric layer, wherein embedding the capacitor comprises:
forming a base portion;
forming a first terminal on a first surface of the base portion, wherein the first terminal is the only terminal on the first surface of the base portion;
forming a second terminal on a second surface of the base portion, the second surface opposite to the first surface, wherein the second terminal is the only terminal on the second surface of the base portion; and
positioning the base portion, the first terminal, and the second terminal in the first dielectric layer.

13. The method of claim 12, wherein embedding the capacitor further comprises:
forming a first base metal layer between the first surface of the base portion and the first terminal; and
forming a second base metal layer between the second surface of the base portion and the second terminal.

14. The method of claim 12, further comprising:
forming a first terminal interconnect on the first terminal of the capacitor; and
forming a second terminal interconnect on the second terminal of the capacitor.

15. The method of claim 14, wherein the first terminal interconnect is coupled to the first terminal such that a substantial part of a horizontal portion of the first terminal is in contact with the first terminal interconnect.

16. The method of claim 14, wherein the first terminal interconnect is coupled to the first terminal such that a majority of a horizontal portion of the first terminal is in contact with the first terminal interconnect.

17. The method of claim 12, wherein the capacitor comprises a lateral dimension of about 0.5 millimeter (mm) or less and/or a vertical dimension of about 0.1 millimeter (mm) or less.

18. The method of claim 12, further comprising forming a core layer, the core layer comprising a cavity in which the capacitor is located in, the first dielectric layer formed in the substrate such that the first dielectric layer fills the cavity of the core layer and encapsulates the capacitor.

19. The method of claim 19, wherein the core layer comprises a first thickness, and the capacitor comprises a second thickness that is about the same or less than the first thickness.

20. The method of claim 12, wherein the substrate is incorporated into at least one of a music player, a video player, an entertainment unit, a navigation device, a communications device, a mobile device, a mobile phone, a smartphone, a personal digital assistant, a fixed location terminal, a tablet computer, and/or a laptop computer.
